(19) United States
(12) Patent Application Publication
(10) Pub. No.: US 2014/0004666 A1
(43) Pub. Date: Jan. 2, 2014

(54) PASSIVATION OF CARBON NANOTUBES WITH MOLECULAR LAYERS

(71) Applicants: Aaron D. FRANKLIN, Croton on Hudson, NY (US); Shu-Jen HAN, Cortlandt Manor, NY (US); George S. TULEVSKI, White Plains, NY (US)

(72) Inventors: Aaron D. FRANKLIN, Croton on Hudson, NY (US); Shu-Jen HAN, Cortlandt Manor, NY (US); George S. TULEVSKI, White Plains, NY (US)

(73) Assignee: INTERNATIONAL BUSINESS MACHINES CORPORATION, Armonk, NY (US)

(21) Appl. No.: 13/536,829

(22) Filed: Jun. 28, 2012

(51) Int. Cl. H01L 21/336; B82Y 40/00

(52) U.S. Cl. 438/158; 257/E21.409; 977/742

(57) ABSTRACT

A transistor device is fabricated, in one embodiment, by providing an insulator on a substrate and forming a gate embedded in the insulator. A dielectric material is deposited over the gate and insulator forming a dielectric layer. A channel comprising carbon nanotubes is formed on the dielectric layer over the gate. A self-assembled monolayer is formed over at least the channel.

### FIELD OF THE INVENTION

The present invention generally relates to the field of transistors, and more particularly relates to transistors having carbon nanotubes, and method of manufacturing the same.

### BACKGROUND OF THE INVENTION

The integration of carbon nano structures such as carbon nanotubes (CNT) as channel materials in the next generation of electronic devices offers many advantages over the continued scaling of silicon (Si). However, one of the leading challenges for CNT devices is the considerable variation in threshold voltage (Vth) and sizable gate hysteresis. Several methods for reducing the hysteresis in CNTFETs have been published. However, these conventional methods generally fail to reduce device hysteresis to an acceptable level and/or increase the thickness of the gate dielectric. Also, some of these conventional methods allow water and other molecules to diffuse through the polymer and adsorb again near the CNT, which negatively affects device operation.

### SUMMARY OF THE INVENTION

In one embodiment, a method for forming a transistor device is disclosed. The method comprises providing an insulator on a substrate and forming a gate embedded in the insulator. A dielectric material is deposited over the gate and insulator forming a dielectric layer. A channel comprising carbon nanotubes is formed on the dielectric layer over the gate. A self-assembled monolayer is formed over at least the channel.

Other objects, features, and advantages of the present invention will become apparent from the following detailed description. It should be understood, however, that the detailed description and specific examples, while indicating various embodiments of the present invention, are given by way of illustration only and various modifications may naturally be performed without deviating from the present invention.

### BRIEF DESCRIPTION OF THE DRAWINGS

FIG. 1 is a three-dimensional diagram illustrating an insulator layer having been patterned with a trench that marks the footprint and location of a local bottom gate according to one embodiment of the present invention;

FIG. 2 is a three-dimensional diagram illustrating a gate material having been deposited into the trench to form a gate according to one embodiment of the present invention;

FIG. 3 is a three-dimensional diagram illustrating a dielectric layer having been deposited over the insulator and gate according to one embodiment of the present invention;

FIG. 4 is a three-dimensional diagram illustrating a carbon nanotube channel having been formed on the dielectric layer over the gate and source/drain contacts according to one embodiment of the present invention;

FIG. 5 is a cross-sectional view of illustrating a self-assembled monolayer having been deposited over the carbon nanotubes and source/drain contacts according to an embodiment of the present invention;

FIGS. 6-7 are graphs illustrating the I-V curve of four global bottom-gated CNTFETs before and after, respectively, being passivated with hexamethyldisilazane according to one embodiment of the present invention;

FIG. 8 is a graph illustrating the I-V curve of a single bottom-gated CNTFET before and after being passivated with hexamethyldisilazane according to one embodiment of the present invention;

FIG. 9 is an operational flow diagram illustrating one process for forming a transistor device; and

FIG. 10 is a flow diagram of a design process used in semiconductor design, manufacture, and/or test.

### DETAILED DESCRIPTION

As discussed above, one of the leading challenges for carbon nanotube (CNT) devices is the considerable variation in the Vth and sizable gate hysteresis. In order for CNT field-effect transistors (CNTFETs) to be considered as a viable technology, the variation in Vth should be less than 15%, with hysteresis eliminated. Therefore, one or more embodiments of the present invention passivate bottom-gated CNTFETs with a self-assembled monolayer (SAM) for removing/reducing gate hysteresis. One method for passivating CNTFETs is to utilize SAMs to coat the gate dielectric surface, followed by deposition of the CNT channels on top of the SAM. However, this underlying SAM adds to the device gate dielectric thickness, which is unacceptable when considering aggressively scaled CNTFETs for a digital technology. Therefore, instead of passivating the gate dielectric surface with the SAM, one or more embodiments passivate the surface after CNT deposition has taken place. Therefore, the SAM does not add to the dielectric thickness. Another advantage is that the SAM covers the CNT channels, protecting them from adsorbed water molecules that contribute to hysteresis. A further advantage is that this process yields a more consistent and uniform elimination of hysteresis than conventional processes.

FIGS. 1-5 are diagrams illustrating one example of a methodology for fabricating a transistor device having a channel formed from a nanoscale material, such as carbon nanotubes. To begin the fabrication process, an oxidized substrate 501 (FIG. 5) is provided. The oxide, for example, silicon dioxide (SiO₂), on a silicon (Si) substrate serves as an insulator into which a bottom gate will be formed. Namely, the insulator is then patterned to define a region for forming the local bottom gate. FIG. 1, for example, is a three-dimensional diagram illustrating an insulator 102 having been patterned with a trench 104 that marks the footprint and location of a local bottom gate. The substrate, which would be present beneath insulator 102, is not shown in this depiction. According to one embodiment, the local bottom gate that will be formed in the insulator 102 will provide all of the necessary channel modulation for the device. With such a configuration, doping of the substrate is not needed.

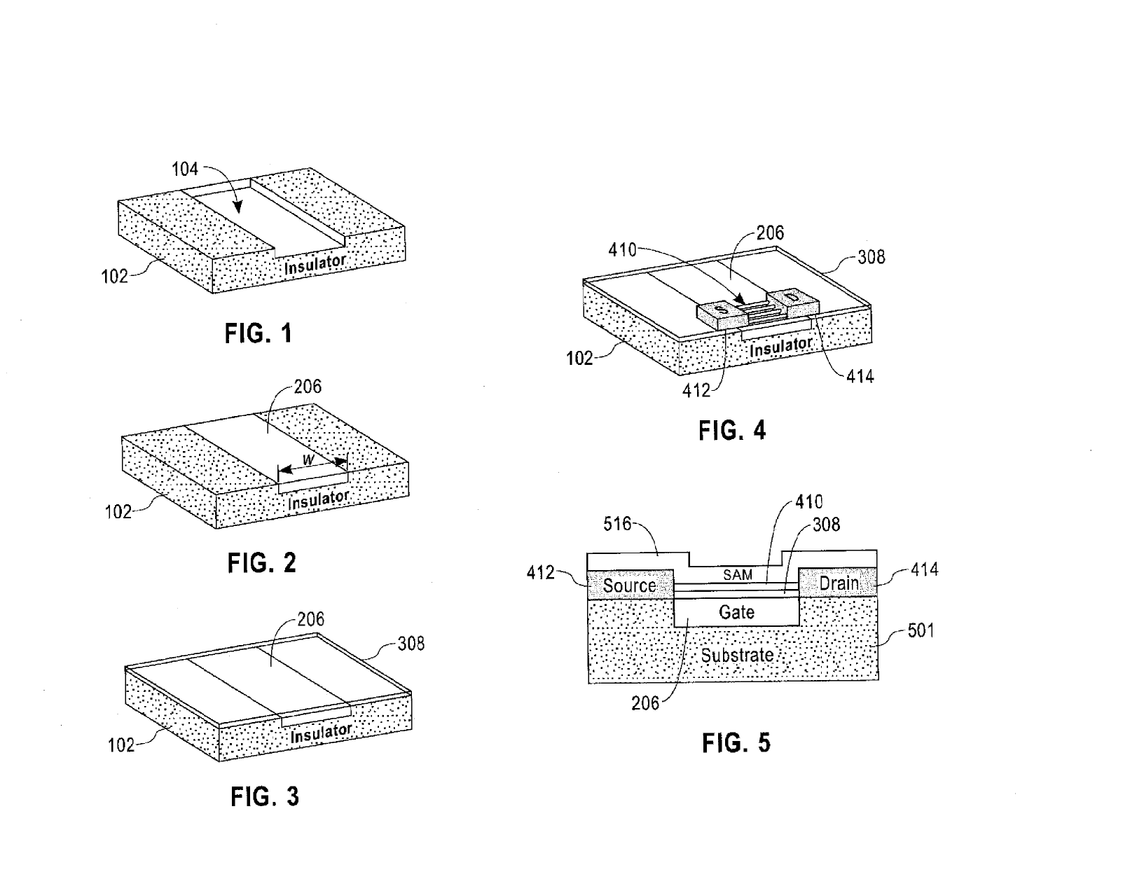

As will be discussed in detail below, an anisotropic dry etch (e.g., reactive ion etching (RIE)) followed by a wet chemical etch to undercut the trench 104 can be performed through a positive resist (e.g., poly (methyl methacrylate) (PMMA)). The undercutting of the trench 104 is done to prevent the build-up of gate material that is to be deposited in the next step, thus providing as smooth a surface as possible for channel formation. As shown in FIG. 2, a suitable gate material is then deposited into the trench 104 to form a gate 206. According to one embodiment, the gate material comprises a metal or a combination of metals deposited, e.g., using electron beam evaporation. Any metal(s) can be used and the particular metal(s) selected may vary for p-channel and n-channel devices to tune the threshold voltage accordingly. By way of example only, suitable gate metals include, but are not limited to aluminum (Al), titanium (Ti) and/or palladium (Pd). In an example provided below, Ti is first deposited into the trench 104 followed by Pd. Alternatively, according to another embodiment, the gate material comprises poly-silicon (poly-Si). The poly-Si can be doped accordingly to attain the desired work function and conductivity. The techniques for poly-Si gate doping are known to those of skill in the art and thus are not discussed further herein.

The result is gate 206 embedded in the insulator 102. As shown in FIG. 2, a top surface of the gate 206 is flush with a surface of the insulator 102. Since the surfaces are flush with one another, the top surface of the gate 206 is thus coplanar with the surface of the insulator 102. The coplanar gate and insulator provide a flat surface on which the channel material can be formed/deposited. It is notable that the dimensions of the gate 206 can be configured to address the specific device needs. By way of example only, a width w of the gate can be varied to tune the channel length and to control an amount by which, if any, the source and drain contacts overlap the gate (see, for example, FIGS. 4 and 5). Additionally, a self-aligned device can be implemented, where the source and drain contacts are aligned directly to the respective edges of the local bottom gate (no overlap, or underlap). Changes to the gate dimensions can be realized, for example, by changing the dimensions of the patterned trench (see above). According to one embodiment, each source or drain contact overlaps the gate by less than or equal to 4 nm (with zero overlap occurring in the case of a self-aligned device as discussed above).

In order to be able to use this local bottom gate configuration as a foundation on which a dielectric and then subsequently a carbon nanotube channel can be built, the gate has to be level or flush (i.e., coplanar) with the surrounding insulator to provide a flat surface (after the gate dielectric is deposited, see below) on which the channel can be formed. This level interface between the gate and surrounding insulator serves to keep the channel material free of any physical distortions, such as kinks or bends, which can adversely affect carrier transport. See, for example, in FIG. 2 where it is shown that a top surface of the gate 206 is coplanar with the surface of insulator 102.

It is notable that, due to production tolerances, in practice the top surface of the gate 206 might end up being slightly higher or slightly lower than the surface of the insulator 102. When the difference between the surfaces is less than or equal to about 5 nm the surfaces are considered substantially coplanar according to the present teachings. Specifically, if the top surface of the gate 206 is less than or equal to about 5 nm higher than the surface of the insulator 102 then the top surface of the gate 206 is considered herein to be substantially coplanar with the surface of the insulator 102. Similarly, if the top surface of the gate 206 is less than or equal to about five 5 lower than the surface of insulator 102 then the top surface of the gate 206 is considered herein to be substantially coplanar with the surface of the insulator 102. A substantially coplanar gate/insulator surface may be achieved using various different methods. One method is to deposit the metal or poly-Si gate material so as to overfill the trench and then polish the deposited gate material, e.g., using chemical-mechanical polishing (CMP), down to the surface of the insulator. The same resist mask, for example PMMA, that was used to etch trench 104 can also be used to fill the gate material. Thus, another method for achieving a substantially coplanar gate/insulator surface is by depositing the gate material through the PMMA resist mask so as to fill (to the top of, but not overfilling) the trench, and then use lift-off in acetone to remove the PMMA, leaving the metal gate flush with the surrounding insulator (the presence of the resist allows for the gate material to remain only in the trenches, since when the resist is removed the gate material on top of the resist washes away with it).

As shown in FIG. 3, a dielectric layer 308, which will serve as a gate dielectric of the device, is then deposited over the insulator 102 and the gate 206. According to one embodiment, the dielectric layer 308 comprises aluminum oxide (Al.sub.2O.sub.3) or hafnium oxide (HfO₂) and is deposited using a chemical vapor deposition (CVD) process such as atomic layer deposition (ALD) to a thickness of less than about 10 nm, e.g., to a thickness of from about three nm to about 10 nm.

Establishing an ultra-thin dielectric lowers the screening length of the device, allowing the channel length to be reduced while maintaining long-channel device behavior. Also, the minimum thickness of a dielectric layer (while not leaky) using one or more embodiments is limited only by the roughness of the gate surface, which can be made nearly atomically smooth using such processes as CMP (see above). In general, a thinner dielectric layer is more advantageous than a thicker dielectric layer. The challenge, however, is that dielectrics can often be leaky (have leakage current) when too thin. Attempts using conventional processes have not been successful in scaling down dielectrics used with nanoscale materials, such as carbon nanotubes, mostly because it is very difficult to uniformly nucleate a dielectric on a carbon nanotube or graphene itself. Advantageously, with one or more embodiments, the thickness of the dielectric layer is completely independent of the channel material, since the dielectric layer is deposited before the carbon nanotubes or graphene are placed. If the gate surface has a roughness of x nm, then the dielectric layer will need to be at least x nm thick in order to provide uniform coverage of the gate surface. Thus, the dielectric layer thickness with one or more embodiments is limited entirely by the gate surface roughness that it must cover.

As an example, when metal gates are employed herein, the gate metal grain size can affect gate surface roughness and thus may be a factor in choosing the thickness of the dielectric layer (i.e., the smaller the grain size, the thinner the dielectric that can be used). However, processes such as controlled deposition environments and/or CMP can be used to obtain smaller grain sizes allowing for thinner dielectrics (down to a single atomic layer, i.e., a monolayer) to be formed without gate leakage.

Next, a carbon nanostructure material such as carbon nanotubes 410 is formed on the dielectric layer 308 over the gate 206, and serves as a channel of the transistor, as shown in FIG. 4. A variety of methods can be used to form the carbon nanotube channel on the dielectric layer 308. By way of example only, transfer techniques such as transfer from a growth substrate for carbon nanotubes can be employed. These transfer processes are known to those of skill in the art and thus are not discussed further herein. Alternatively, the carbon nanotubes 410 can be deposited on the dielectric layer 308, for example, from a carbon nanotube solution using a spin-casting process, or can be grown on the dielectric layer (e.g., by patterning some catalyst particles near the gate and then using CVD to synthesize carbon nanotubes which grow over the neighboring gate). As shown in FIG. 4, source and drain contacts 412, 414, labeled “S” and “D”, respectively, are also formed on opposite sides of the carbon nanotube channel. The source and drain contacts 412, 414 can be formed by depositing metal through a resist mask and then lifting off. A variety of other suitable methods known to those of skill in the art may be similarly employed to form the source and drain contacts.

After the source/drain contacts 412, 414 have been formed a SAM layer 516 is formed over the source/drain contacts 412, 414 and the carbon nanotubes 410, as shown in FIG. 5. By forming the SAM layer 516 over the source/drain contacts 412, 414 and the carbon nanotubes 410 the thickness of the dielectric layer 308 is not increased. The SAM layer 516 passivates the hydroxylated oxide surface and the carbon nanotube channel. This prevents adsorbates such as water and oxygen from reattaching and acting as charge traps. The SAM layer 516, in one embodiment, comprises hexamethyldisilazane (HMDS) or octadecyltrichlorosilane ODTS), although other materials are applicable as well. The SAM layer 516 is formed/deposited, for example, using a chemical vapor deposition (CVD) process at an elevated temperature ranging from 70 to 300° C. (e.g., 150° C.) at, for example, a low vacuum in the 1-10 ton range, for 6-48 hours. However, other temperatures, pressures, and durations are applicable as well. This allows for the removal of adsorbed water and oxygen as the SAM layer 516 is reactively deposited. Also, the deposition time is such that a complete monolayer is formed.

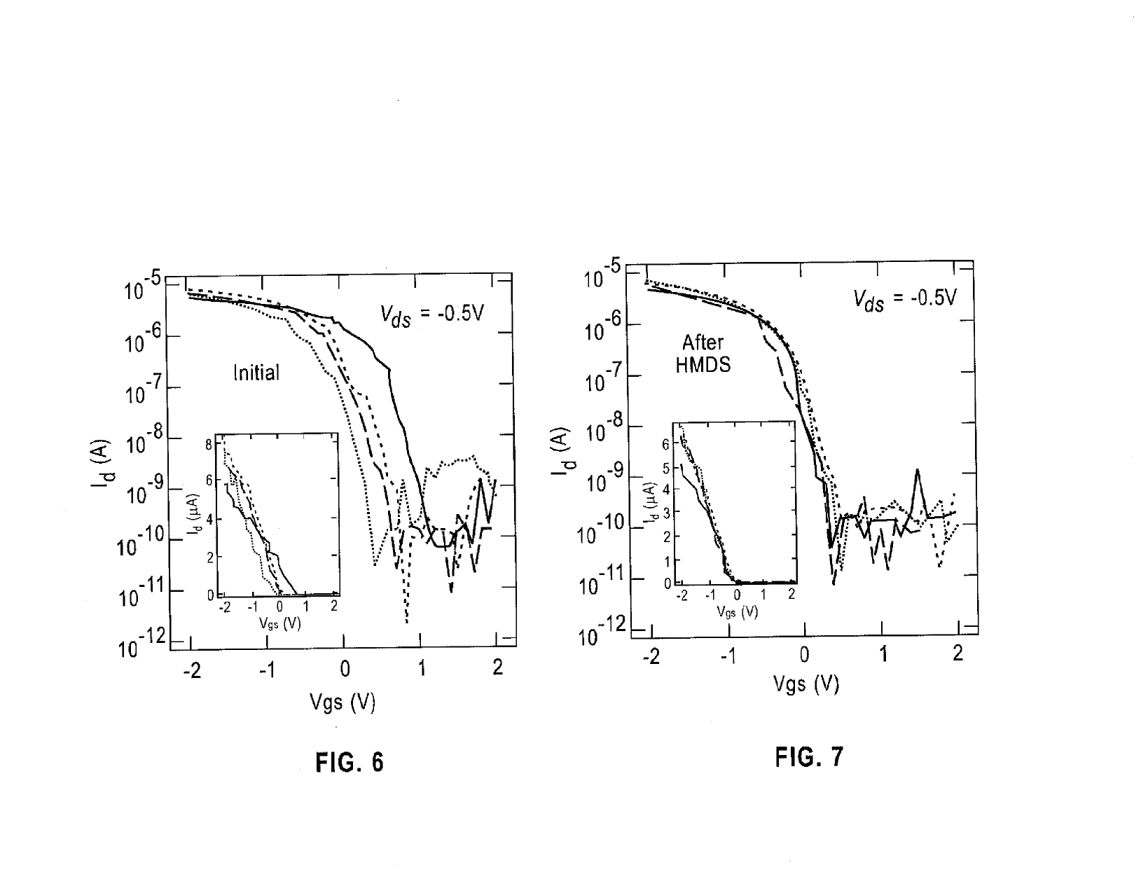

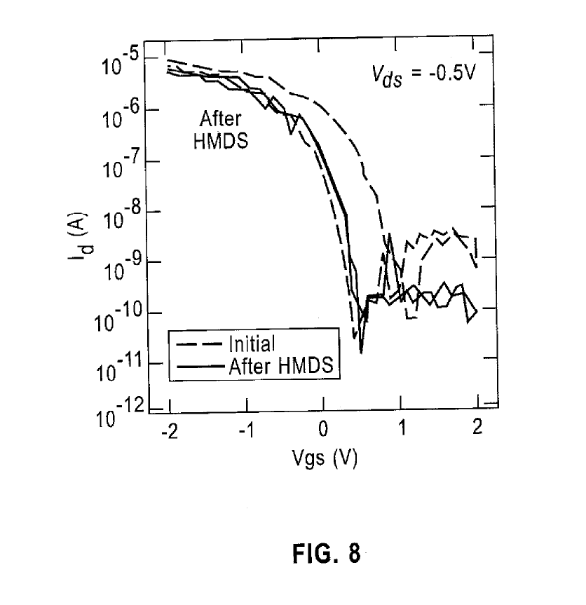

By depositing the SAM layer 516 over the source/drain contacts 412, 414 and the carbon nanotubes 410 the device is passivated and hysteresis is removed (or at least reduced to less than 15%), as shown in FIGS. 6-8. For example, FIGS. 5-6 are graphs based on data from global bottom-gated CNTFETs that were passivated with HMDS according to one or more embodiments of the present invention. The dielectric of these devices was 10 nm SiO2 and the devices had a channel length of 80 nm with Pd source/drain contacts. FIG. 6 shows an I-V curve of four global bottom-gated CNTFETs with the same CNT channel prior to deposition of the SAM layer 516. As can be seen, the Vth across the devices is very inconsistent. However, as shown in FIG. 7, after the SAM layer 516 was deposited, a dramatic improvement in the Vth can be seen. FIG. 8 shows similar results for a single bottom-gated CNTFET. Therefore, by depositing a SAM layer 516 over the over the source/drain contacts 412, 414 and the carbon nanotubes 410 of a bottom-gated (or local gated) CNTFET the dielectric thickness is not increased and the CNT channel are protected from adsorbed water molecules that contribute to hysteresis. This process yields a more consistent and uniform elimination of hysteresis than conventional processes.

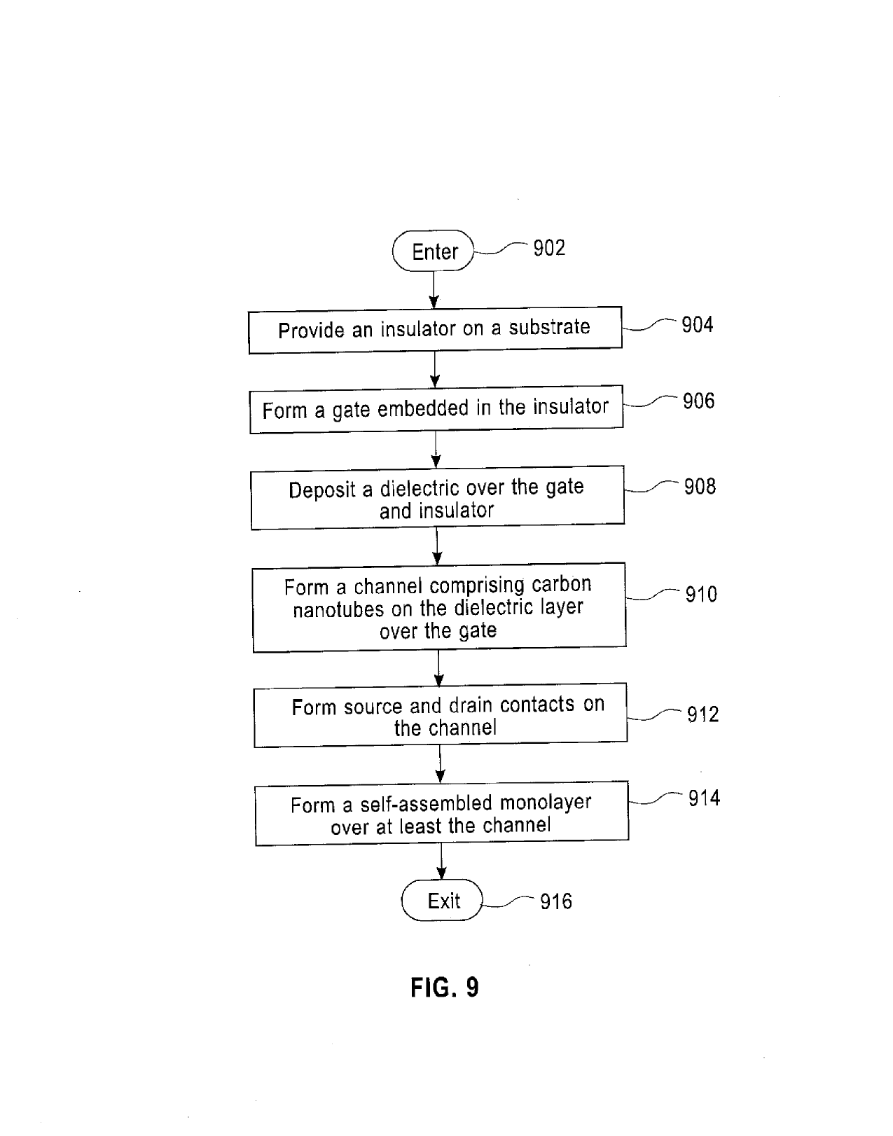

FIG. 9 is an operational flow diagram illustrating a process for forming a transistor. The operational flow diagram of FIG. 9 begins at step 902 and flows directly to step 904. An insulator 102, at step 904, is provided on a substrate. A gate 206, at step 906, is formed embedded in the insulator 102. A dielectric 308, at step 908, is deposited over the gate 206 and insulator 102. A channel comprising carbon nanotubes 410, at step 910, is formed over the gate 206. A source contact 412 and a drain contact 414, at step 912, are formed on opposite sides of the channel. A self-assembled monolayer 516, at step 914, is formed over at least the channel comprising the carbon nanotubes 410. The control flow exits at step 916.

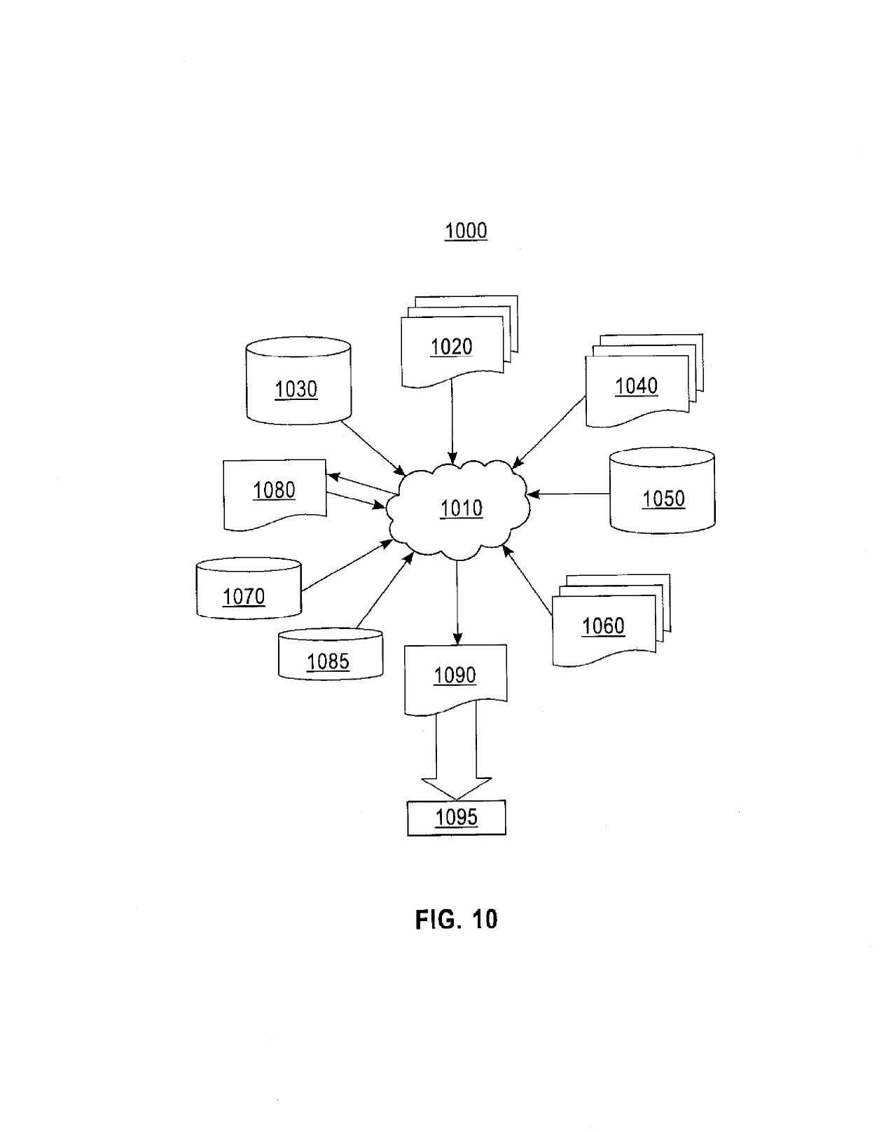

FIG. 10 shows a block diagram of an exemplary design flow 1000 used for example, in semiconductor IC logic design, simulation, test, layout, and manufacture. Design flow 1000 includes processes and mechanisms for processing design structures or devices to generate logically or otherwise functionally equivalent representations of the design structures and/or devices described above and shown in FIGS. 1-5. The design structures processed and/or generated by design flow 1000 may be encoded on computer-readable transmission or storage media to include data and/or instructions that when executed or otherwise processed on a data processing system generate a logically, structurally, mechanically, or otherwise functionally equivalent representation of hardware components, circuits, devices, or systems. Design flow 1000 may vary depending on the type of representation being designed. For example, a design flow 1000 for building an application specific IC (ASIC) may differ from a design flow 1000 for designing a standard component or from a design flow 1000 for instantiating the design into a programmable array, for example a programmable gate array (PGA) or a field programmable gate array (FPGA) offered by Altera® Inc. or Xilinx® Inc.

FIG. 10 illustrates multiple such design structures including an input design structure 1020 that is preferably processed by a design process 1010. Design structure 1020 may be a logical simulation design structure generated and processed by design process 1010 to produce a logically equivalent functional representation of a hardware device. Design structure 1020 may also or alternatively comprise data and/or program instructions that when processed by design process 1010, generate a functional representation of the physical structure of a hardware device. Whether representing functional and/or structural design features, design structure 1020 may be generated using electronic computer-aided design (ECAD) such as implemented by a core developer/designer. When encoded on a machine-readable data transmission, gate array, or storage medium, design structure 1020 may be accessed and processed by one or more hardware and/or software modules within design process 1010 to simulate or otherwise functionally represent an electronic component, circuit, electronic or logic module, apparatus, device, or system such as those shown in FIGS. 1-5. As such, design structure 1020 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 1010 preferably employs and incorporates hardware and/or software modules for synthesizing, translating, or otherwise processing a design/simulation functional equivalent of the components, circuits, devices, or logic structures shown in FIGS. 1-5 to generate a netlist 1080 which may contain design structures such as design structure 1060. Netlist 1080 may comprise, for example, compiled or otherwise processed data structures representing a list of wires, discrete components, logic gates, control circuits, I/O devices, models, etc. that describes the connections to other elements and circuits in an integrated circuit design. Netlist 1080 may be synthesized using an iterative process in which netlist 1080 is resynthesized one or more times depending on design specifications and parameters for the device. As with other design structure types described herein, netlist 1080 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 1010 may include hardware and software modules for processing a variety of input data structure types including netlist 1080. Such data structure types may reside, for example, within library elements 1030 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 1040, characterization data 1050, verification data 1060, design rules 1070, and test data files 1085 which may include input test patterns, output test results, and other testing information. Design process 1010 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 1010 without deviating from the scope and spirit of the invention. Design process 1010 may also include modules for performing standard circuit design processes such as timing analysis, verification, design rule checking, place and route operations, etc.

Design process 1010 employs and incorporates logic and physical design tools such as HDL compilers and simulation model build tools to process design structure 1020 together with some or all of the depicted supporting data structures along with any additional mechanical design or data (if applicable), to generate a second design structure 1090. Design structure 1090 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 1020, design structure 1090 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-5. In one embodiment, design structure 1090 may comprise a compiled, executable HDL simulation model that functionally simulates the devices shown in FIGS. 1-5.

Design structure 1090 may also employ a data format used for the exchange of layout data of integrated circuits and/or symbolic data format (e.g., information stored in a GDSII (GDS2), GL1, OASIS, map files, or any other suitable format for storing such design data structures). Design structure 1090 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-5. Design structure 1090 may then proceed to a stage 1095 where, for example, design structure 1090: proceeds to tape-out, is released to manufacturing, is released to a mask house, is sent to another design house, is sent back to the customer, etc.

It should be noted that some features of the present invention may be used in an embodiment thereof without use of other features of the present invention. As such, the foregoing description should be considered as merely illustrative of the principles, teachings, examples, and exemplary embodiments of the present invention, and not a limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The methods as discussed above are used in the fabrication of integrated circuit chips.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products (such as, but not limited to, an information processing system) having a display, a keyboard, or other input device, and a central processor.

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one as or more than one. The term plurality, as used herein, is defined as two as or more than two. Plural and singular terms are the same unless expressly stated otherwise. The term another, as used herein, is defined as at least a second or more. The terms including and/or having, as used herein, are defined as comprising (i.e., open language). The term coupled, as used herein, is defined as connected, although not necessarily directly, and not necessarily mechanically. The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method for fabricating a transistor device, the method comprising:
providing an insulator on a substrate;
forming a gate embedded in the insulator;
depositing a dielectric material over the gate and insulator forming a dielectric layer;
forming a channel comprising carbon nanotubes on the dielectric layer over the gate; and
forming a self-assembled monolayer over at least the channel, wherein the self-assembled monolayer is formed over and contacts a top surface of the carbon nanotubes.

2. The method of claim 1, further comprising:
forming a source contact and a drain contact on opposite sides of the channel, wherein the self-assembled monolayer is also formed on the source contact and the drain contact.

3. The method of claim 1, wherein the self-assembled monolayer is formed over at least the channel using chemical vapor deposition.

4. The method of claim 1, wherein the self-assembled monolayer comprises one of hexamethyldisilazane and octadecyltrichlorosilane.

5. The method of claim 1, wherein the gate is formed with a top surface of the gate being substantially coplanar with a surface of the insulator.

6. The method of claim 1, wherein forming the gate embedded in the insulator comprises:
forming a trench in the insulator;
filling the trench with a gate material; and
polishing the gate material down to a surface of the insulator.

7. The method of claim 6, wherein the gate material comprises one or more metals.

8. The method of claim 6, wherein the gate material comprises poly-silicon.

9. The method of claim 6, wherein forming the trench in the insulator further comprises undercutting the trench.

10. The method of claim 9, wherein the trench is undercut using a wet chemical etch.

11. The method of claim 1, wherein the dielectric layer is deposited over the gate and insulator using atomic layer deposition.

12. The method of claim 1, wherein forming the channel comprises:
transferring the carbon nanotubes to the dielectric layer from a growth substrate.

13. The method of claim 1, wherein forming the channel comprises:
depositing the carbon nanotubes on the dielectric layer from a carbon nanotube solution using a spin-casting process.

14. The method of claim 1, wherein forming the channel comprises:
growing the carbon nanotubes on the dielectric layer.
